(19) United States
(12) Patent Application Publication
(10) Pub. No.: US 2014/0159200 A1
(43) Pub. Date: Jun. 12, 2014

(54) HIGH-DENSITY STACKED PLANAR METAL-INSULATOR-METAL CAPACITOR STRUCTURE AND METHOD FOR MANUFACTURING SAME

(71) Applicants: Alvin Leng Sun Loke, Fort Collins, CO (US); Tin Tin Wee, Fort Collins, CO (US)

(72) Inventors: Alvin Leng Sun Loke, Fort Collins, CO (US); Tin Tin Wee, Fort Collins, CO (US)

(21) Appl. No.: 13/730,552

(22) Filed: Dec. 28, 2012

Related U.S. Application Data
(60) Provisional application No. 61/735,004, filed on Dec. 8, 2012.

(51) Int. Cl. H01L 49/02

(52) U.S. Cl. CPC H01L 28/40
USPC 257/532; 438/396

(57) ABSTRACT

An embodiment of a high-density, stacked, planar metal-insulator-metal (MIM) capacitor structure includes a stack of planar electrodes and interposing dielectric layers. Vertically-alternating electrodes are horizontally-staggered, and vias are formed through the multiple electrodes, so that electrical connection is made circumferentially through the via sidewalls to multiple electrodes through which a given via passes. An MIM capacitor incorporating a multiple-level capacitor stack may be fabricated by repeated usage of the same mask operation for each incremental capacitor stack level, and without requiring additional masks beyond those utilized for the first such level.

### CROSS-REFERENCE TO RELATED APPLICATION

This application claims the benefit under 35 U.S.C. §119(e) of U.S. Provisional Application No. 61/735,004, filed Dec. 8, 2012, entitled “High-Density Stacked Planar Metal-Insulator-Metal Capacitor Structure and Method for Manufacturing Same” by Alvin Leng Sun Loke and Tin Tin Wee, which application is hereby incorporated by reference in its entirety.

### BACKGROUND

1. Technical Field

This application relates to metal-insulator-metal capacitor structures, and more particularly relates to monolithic planar metal-insulator-metal capacitor structures.

2. Description of the Related Art

Integrated circuit packaging delivers power to an integrated circuit die through package interconnects that are instrinsically inductive. An abrupt change in current flowing through such inductive package interconnects, due to a rapid change in circuit activity on the die, will cause a significant power supply voltage droop at the integrated circuit die. These power supply voltage droops cause performance degradation, and impose design complexity and conservative performance margining to prevent timing failures when circuit delays suddenly increase during such droops. In many situations, it is extremely important to incorporate decoupling capacitance to reduce the magnitude of these sudden power supply voltage droops. On-chip decoupling capacitance is desirable because it is local to the integrated circuit, and its effectiveness at higher frequencies is not degraded by parasitic series resistance or inductive package interconnects.

### SUMMARY OF EMBODIMENTS

Accordingly, it would be desirable to provide higher on-chip capacitance density, to therefore reduce the magnitude of power supply voltage droops. This would mitigate system performance degradation and circumvent some amount of design complexity. It would be further desirable to provide such higher on-chip capacitance density without a substantial increase in process complexity or cost.

In one example embodiment, a high-density, stacked, planar metal-insulator-metal (MIM) capacitor structure includes a stack of planar electrodes and interposing dielectric layers. Vertically-alternating electrodes are horizontally-staggered, and vias are formed through the multiple electrodes, so that electrical connection is made circumferentially through the via sidewalls to multiple electrodes through which a given via passes. A MIM capacitor incorporating a multiple-level capacitor stack may be fabricated by repeated usage of the same mask operation for each incremental capacitor stack level, and without requiring additional masks beyond those utilized for the first such level.

Another example embodiment provides a method for fabricating a metal-insulator-metal capacitor structure, which includes forming a vertical stack of planar electrodes and interposing dielectric layers in an overlap region. Each of a first set of one or more electrodes of the vertical stack extends beyond the overlap region to a first region but not to a second region, and each of a second set of two or more electrodes of the vertical stack extends beyond the overlap region to the second region but not to the first region. The method also includes forming vias for a first conductor layer above the vertical stack to a second conductor layer below the vertical stack. Each via has a sidewall, and each of a first set of one or more of the vias is formed in the first region through and is electrically connected at its sidewall to each of the first set of one or more electrodes of the vertical stack. Each of a second set of one or more of the vias is formed in the second region through and is electrically connected at its sidewall to each of the second set of two or more electrodes of the vertical stack.

In some embodiments, after forming the vertical stack of planar electrodes and interposing dielectric layers, and before forming the vias, the method includes removing the interposing dielectric layers outside the planar electrodes.

In some embodiments, before forming the vertical stack of planar electrodes and interposing dielectric layers, the method includes forming a lower via dielectric layer. After forming the vertical stack of planar electrodes and interposing dielectric layers, and before forming the vias, the method includes forming an upper via dielectric layer. Each of the vias is formed through the upper via dielectric layer and through the lower via dielectric layer to connect the first conductor layer to the second conductor layer.

In some embodiments, each electrode of the first set of one or more electrodes is vertically adjacent to an electrode of the second set of two or more electrodes, and vertically-adjacent electrodes are horizontally-staggered. In some embodiments, each electrode of the first set of one or more electrodes is patterned using a first mask, and each electrode of the second set of two or more electrodes is patterned using a second mask. In some embodiments, each respective via is fully enclosed by each of the respective set of electrodes through which the respective via is formed, and the electrical connection for each respective via is made circumferentially through the respective via sidewall to each of the respective set of electrodes through which the respective via is formed.

In some embodiments, the first set of one or more of the vias includes multiple vias, and the second set of one or more of the vias includes multiple vias. In some embodiments, each of the interposing dielectric layers includes a halfnium-based dielectric.

In some embodiments, forming a vertical stack of planar electrodes and interposing dielectric layers includes patterning a first electrode layer using a first mask to form a first electrode, then patterning a second electrode layer using a second mask different than the first mask to form a second electrode that is horizontally-staggered relative to the first electrode, and then patterning a third electrode layer using the first mask to form a third electrode that is horizontally-aligned with the first electrode. In some of these embodiments, after forming the vertical stack of planar electrodes and interposing dielectric layers, and before forming the vias, the method also includes removing the interposing dielectric layers outside the first, second, and third electrodes.

Another example embodiment provides a method for fabricating a metal-insulator-metal capacitor structure, which includes forming a vertical stack of planar electrodes and interposing dielectric layers, wherein vertically-adjacent electrodes are horizontally-staggered. The method also includes forming vias from a first conductor layer above the vertical stack to a second conductor layer below the vertical stack. Each via has a sidewall, and each of a first plurality of the vias is formed through and is electrically connected at its sidewall to each of a first set of one or more electrodes of the vertical stack. Each of a second plurality of the vias is formed through and is electrically connected at its sidewall to each of a second set of two or more electrodes of the vertical stack.

In some embodiments, the electrical connection for each respective one of the second plurality of vias is made circumferentially through the respective via sidewall to each of the second set of two or more electrodes through which the respective via is formed.

In some embodiments, forming a vertical stack of planar electrodes and interposing dielectric layers includes patterning a first electrode layer using a first mask to form a first electrode, patterning a second electrode layer using a second mask to form a second electrode that is horizontally-staggered relative to the first electrode, and patterning a third electrode layer using the first mask to form a third electrode that is horizontally-aligned with the first electrode.

Another example embodiment provides an apparatus including a metal-insulator-metal (MIM) capacitor structure, which includes a vertical stack of planar electrodes and interposing dielectric layers in an overlap region. Each of a first set of one or more electrodes of the vertical stack extends beyond the overlap region to a first region but not to a second region, and each of a second set of two or more electrodes of the vertical stack extends beyond the overlap region to the second region but not to the first region. Also included are plural vias from a first conductor layer above the vertical stack to a second conductor layer below the vertical stack. Each via has a sidewall. Each of a first set of one or more of the vias is formed in the first region through and is electrically connected at its sidewall to each of the first set of one or more electrodes of the vertical stack. Each of a second set of one or more of the vias is formed in the second region through and is electrically connected at its sidewall to each of the second set of two or more electrodes of the vertical stack.

In some embodiments, the interposing dielectric layers are disposed within the vertical stack of planar electrodes, and are absent outside the vertical stack of planar electrodes.

In some embodiments, the apparatus includes a lower via dielectric layer between the second metal layer and the vertical stack, and an upper via dielectric layer between the first metal layer and the vertical stack. Each of the vias is formed through the upper via dielectric layer and through the lower via dielectric layer to connect the first conductor layer to the second conductor layer.

In some embodiments, each electrode of the first set of one or more electrodes is vertically adjacent to an electrode of the second set of two or more electrodes, and vertically-adjacent electrodes are horizontally-staggered.

In some embodiments, each respective via is fully enclosed by each of the respective set of electrodes through which the respective via is formed, and the electrical connection for each respective via is made circumferentially through the respective via sidewall to each of the respective set of electrodes through which the respective via is formed.

In some embodiments, the first set of one or more of the vias includes multiple vias, and the second set of one or more of the vias includes multiple vias.

In some embodiments, the second set of two or more electrodes includes a first electrode and a third electrode that is above and horizontally-aligned with the first electrode. The first set of one or more electrodes includes a second electrode that is above and horizontally-staggered relative to the first electrode, and below the third electrode. The interposing dielectric layers include a first interposing dielectric layer between the first and second electrodes, and a second interposing dielectric layer between the second and third electrodes.

In some embodiments, the metal-insulator-metal capacitor structure is disposed on an integrated circuit. In some embodiments, the metal-insulator-metal capacitor structure is disposed on an interposer structure.

In some embodiments, an apparatus includes a metal-insulator-metal (MIM) capacitor structure. In some embodiments, the apparatus includes a vertical stack of planar electrodes and interposing dielectric layers, in which vertically-adjacent electrodes are horizontally-staggered. Also included are a first plurality and a second plurality of vias from a first conductor layer above the vertical stack to a second conductor layer below the vertical stack. Each via has a sidewall, and each of the first plurality of vias is formed through and is electrically connected at its sidewall to each of a first set of one or more electrodes of the vertical stack. Each of the second plurality of vias is formed through and is electrically connected at its sidewall to each of a second set of two or more electrodes of the vertical stack.

In some embodiments, the vertical stack includes a first electrode, a second electrode that is horizontally-staggered (i.e., horizontally-offset) relative to the first electrode, and a third electrode that is horizontally-aligned with the first electrode. The first set of one or more electrodes includes the second electrode, and the second set of two or more electrodes includes the first and third electrodes.

In some embodiments, the electrical connection for each respective one of the second plurality of vias is made circumferentially through the respective via sidewall to each of the second set of two or more electrodes through which the respective via is formed.

In some embodiments, the metal-insulator-metal capacitor structure is disposed on an integrated circuit. In some embodiments, the metal-insulator-metal capacitor structure is disposed on an interposer structure.

A computer readable storage medium including data structures encoding an aspect of a metal-insulator-metal capacitor structure is provided in some embodiments. Such a metal-insulator-metal capacitor structure includes a vertical stack of planar electrodes and interposing dielectric layers in an overlap region. Each of a first set of one or more electrodes of the vertical stack extends beyond the overlap region to a first region but not to a second region, and each of a second set of two or more electrodes of the vertical stack extends beyond the overlap region to the second region but not to the first region. Also included are plural vias from a first conductor layer above the vertical stack to a second conductor layer below the vertical stack. Each via has a sidewall, and each of a first set of one or more of the vias is formed in the first region through and is electrically connected at its sidewall to each of the first set of one or more electrodes of the vertical stack. Each of a second set of one or more of the vias is formed in the second region through and is electrically connected at its sidewall to each of the second set of two or more electrodes of the vertical stack.

In some embodiments, the interposing dielectric layers are disposed within the vertical stack of planar electrodes, and are absent outside the vertical stack of planar electrodes.

In some embodiments, the metal-insulator-metal capacitor structure includes a lower via dielectric layer between the second metal layer and the vertical stack, and an upper via dielectric layer between the first metal layer and the vertical stack. Each of the vias is formed through the upper via dielectric layer and through the lower via dielectric layer to connect the first conductor layer to the second conductor layer.

In some embodiments, each respective via is fully enclosed by each of the respective set of electrodes through which the respective via is formed, and the electrical connection for each respective via is made circumferentially through the respective via sidewall to each of the respective set of electrodes through which the respective via is formed.

The inventive aspects described herein are specifically contemplated to be used alone as well as in various combinations. The invention in several aspects is contemplated to include circuits (including integrated circuits), related methods of fabrication, systems incorporating same, and computer-readable storage media encodings of such circuits and methods and systems, all as described herein in greater detail and as set forth in the appended claims.

The foregoing is a summary and thus contains, by necessity, simplifications, generalizations and omissions of detail. Consequently, those skilled in the art will appreciate that the foregoing summary of embodiments is illustrative only and is not intended to be in any way limiting of the invention. It is only the claims, including all equivalents, in this or any application claiming priority to this application, that are intended to define the invention.

### BRIEF DESCRIPTION OF THE DRAWINGS

The disclosed embodiments may be better understood, and their features and advantages made apparent to those skilled in the art by referencing the accompanying drawings.

FIGS. 1-12 are cross-sectional views depicting a process flow for manufacturing a stacked MIM capacitor structure, according to some embodiments.

FIGS. 13-16 are cross-sectional views depicting a process flow for manufacturing a stacked MIM capacitor structure, according to some embodiments.

FIG. 17 is a top view depicting a layout of a stacked MIM capacitor structure, according to some embodiments.

FIG. 18 is a top view depicting a layout of a stacked MIM capacitor structure, according to some embodiments.

FIG. 19 is a top view depicting a layout of a stacked MIM capacitor structure, according to some embodiments.

FIG. 20 is a top view depicting a layout of a stacked MIM capacitor structure, according to some embodiments.

The use of the same reference symbols in different drawings indicates similar or identical items.

### DETAILED DESCRIPTION

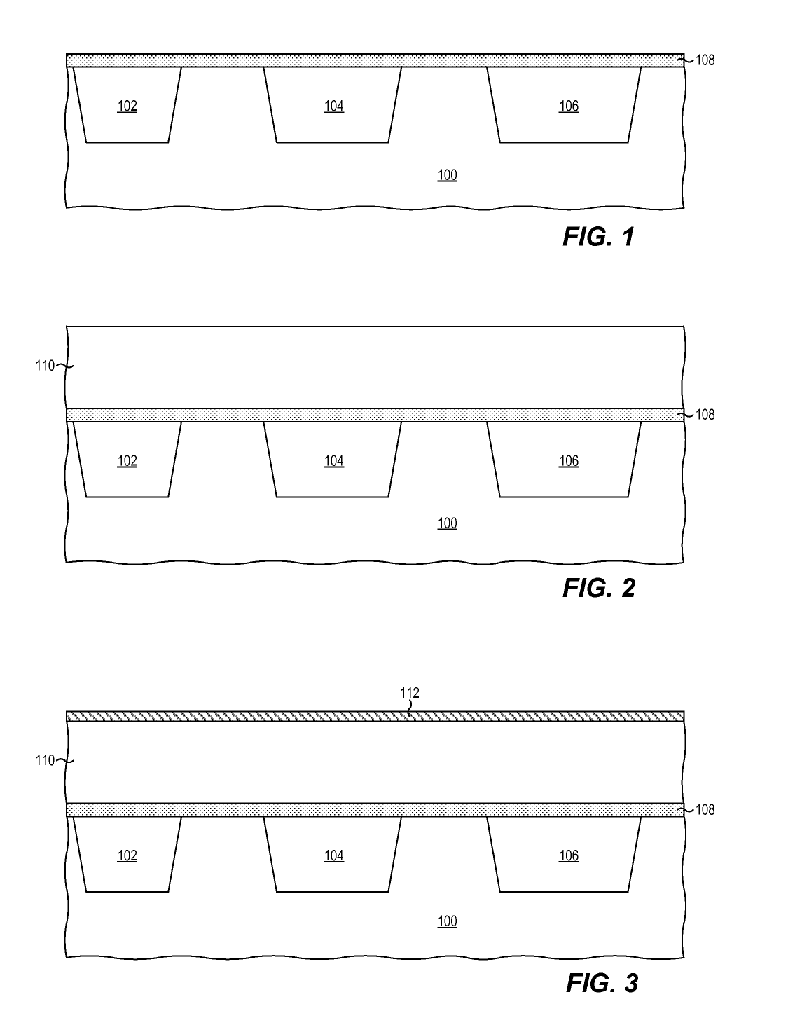

FIGS. 1-12 depict an embodiment of a process flow for manufacturing a stacked MIM capacitor structure. This process flow begins after completing any Metal/Via process module, such as a conventional damascene copper interconnect integration.

In FIG. 1, metal lines 102, 104, 106 represent features of a given metal layer which are formed on dielectric layer 100. For convenience these metal line 102, 104, 106 will be described as being formed on a Metal-1 layer. A dielectric barrier 108 is also shown formed on the top surface of the dielectric layer 100 and the metal lines 102, 104, 106.

The MIM capacitor structure is more effective in reducing power supply voltage droop from package inductance when the MIM capacitor structure is located near the highest metal layer, since metal lines on such metal layers are frequently used to route power supply voltages and are frequently much thicker and wider than metal lines on lower layers. Consequently, no limiting inference should be drawn from the description herein making reference to a Metal-1 layer.

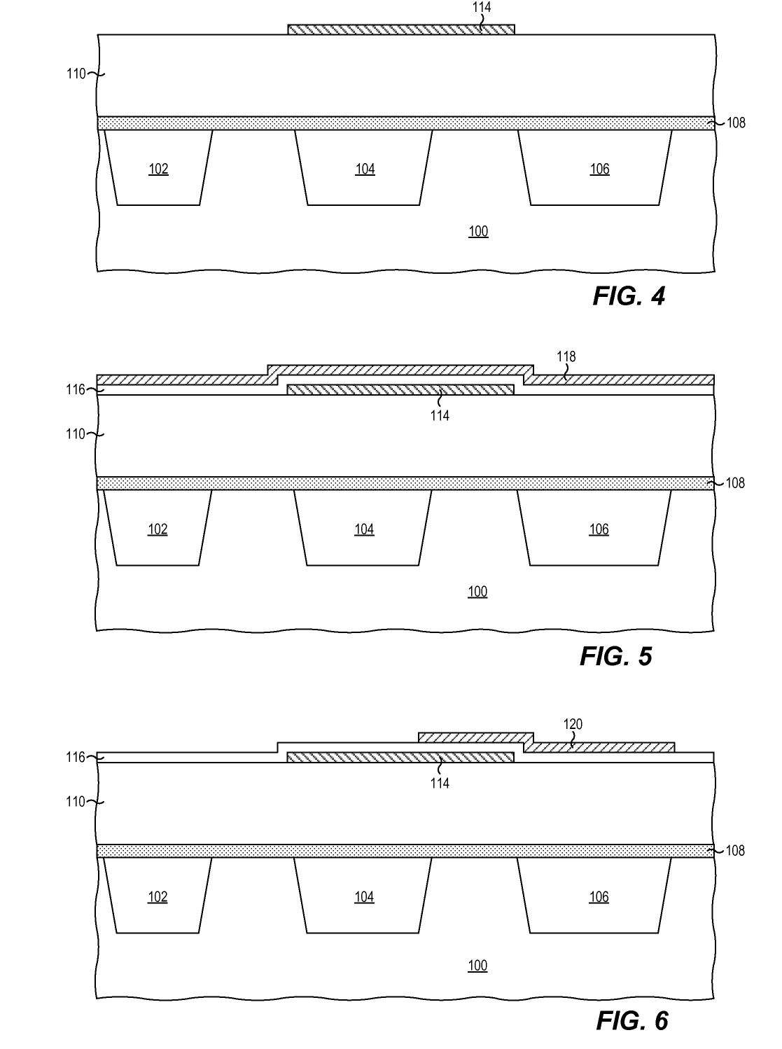

Referring now to FIG. 2, a lower via dielectric layer 110 is deposited to approximately half the total desired via dielectric thickness. A first electrode layer 112 is then blanket deposited on the surface of the lower via dielectric layer 110, as shown in FIG. 3. This first electrode layer 112 is patterned with a first photolithography mask, and a subsequent subtractive etch performed, to form a first electrode 114, as shown in FIG. 4.

Referring now to FIG. 5, a first capacitor dielectric layer 116 is blanket deposited, then a second electrode layer 118 is blanket deposited. This second electrode layer 118 is patterned with a second photolithography mask, and a subsequent subtractive etch performed, to form a second electrode 120, as shown in FIG. 6. The second electrode 120 is horizontally staggered (i.e., offset) relative to the first electrode 114.

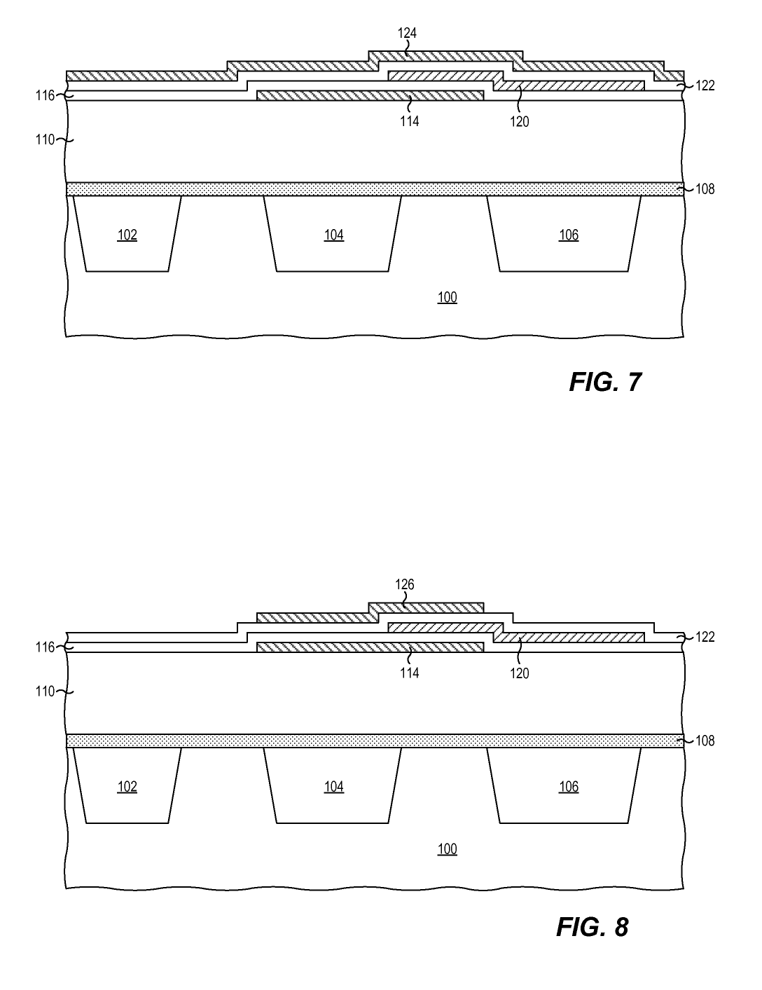

Referring now to FIG. 7, a second capacitor dielectric layer 122 is blanket deposited, then a third electrode layer 124 is blanket deposited. This third electrode layer 124 is patterned with the first photolithography mask (i.e., the same mask used to pattern the first electrode 114), and a subsequent subtractive etch performed, to form a third electrode 126, as shown in FIG. 8. The third electrode 126 is horizontally staggered relative to the second electrode 120, and is horizontally aligned to (i.e., coincident with) the first electrode 114.

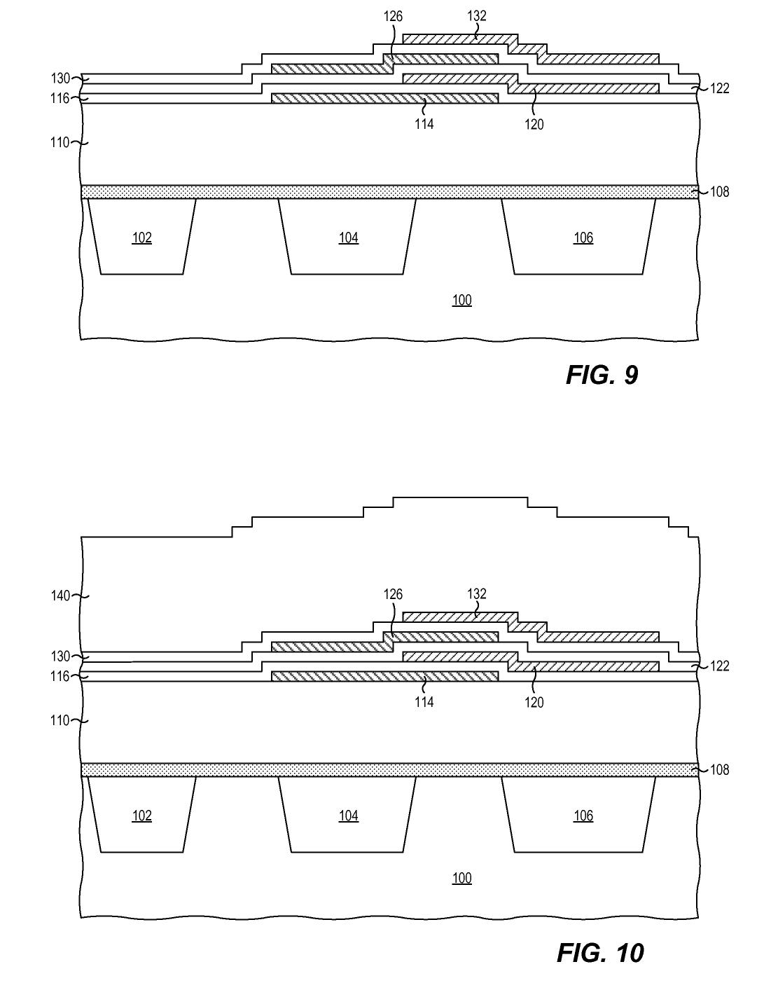

Referring now to FIG. 9, a third capacitor dielectric layer 130 is blanket deposited, then a fourth electrode layer (not shown) is blanket deposited, patterned with the second photolithography mask (i.e., the same mask used to pattern the second electrode 120), and a subsequent subtractive etch performed, to form a fourth electrode 132. Additional numbers of alternating dielectric layers and electrode layers may be deposited, patterned, and etched to form additional electrodes for the MIM capacitor structure. Each such capacitor stack level (i.e., including the corresponding dielectric layer and corresponding electrode layer) may be implemented using a single additional photolithographic masking operation for each incremental level of the capacitor stack, and without requiring additional masks beyond those utilized for the first level of the capacitor stack.

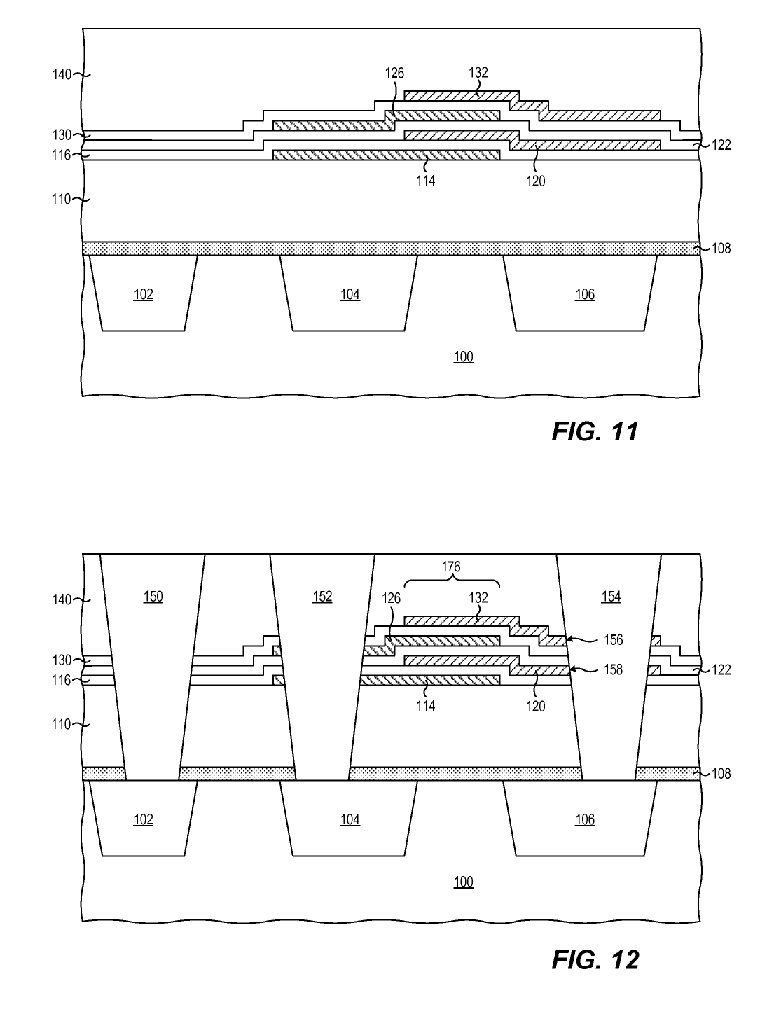

Referring now to FIG. 10, an upper via dielectric layer 140 is deposited to approximately half the total desired via dielectric thickness, such that the lower via dielectric layer 110 and the upper via dielectric layer 140 together provide the total desired via dielectric thickness (with minor contribution from the capacitor dielectric layers 116, 122, 130). The upper surface of this upper via dielectric layer 140 may then be planarized (e.g., using chemical-mechanical polishing (CMP) techniques) to remove the residual topography that results from patterning of the underlying capacitor electrodes. The resulting structure is shown in FIG. 11.

Referring now to FIG. 12, vias 150, 152, 154 are formed to contact underlying metal lines 102, 104, 106, respectively. Such vias may be formed using conventional single-damascene via processing. These vias may also be formed using conventional dual-damascene processing of via and overlying metal. Via 150 is formed through a stack of dielectric layers 140, 130, 122, 116, 110 and is not electrically connected to either plate of the MIM capacitor.

Via 152 is formed through the same stack of dielectric layers, but also is formed through the first electrode 114 and the third electrode 126. These two electrodes 114, 126 make physical and electrical contact to the via 152 sidewall, and thus are both connected to the circuit node to which via 152 belongs, such as a power supply or ground node. Similarly, via 154 is formed through the second electrode 120 and the fourth electrode 132. These two electrodes 120, 132 make physical and electrical contact to the via 154 sidewall, and thus are both connected to the circuit node to which via 154 belongs. In some embodiments, via 152 is connected to a VDD power supply grid, and via 154 is connected to a ground grid.

As may be appreciated, vertically-alternating electrodes are horizontally-staggered so that the vias making contact to one group of electrodes do not inadvertently form an electrical short with the other group of electrodes. In this example, the first and third electrodes 114, 126 are staggered (i.e., offset) relative to the alternating second and fourth electrodes 120, 132, so that via 152 makes contact to electrodes 114, 126 without contacting electrodes 120, 132, and so that via 154 makes contact to electrodes 120, 132 without contacting electrodes 114, 126.

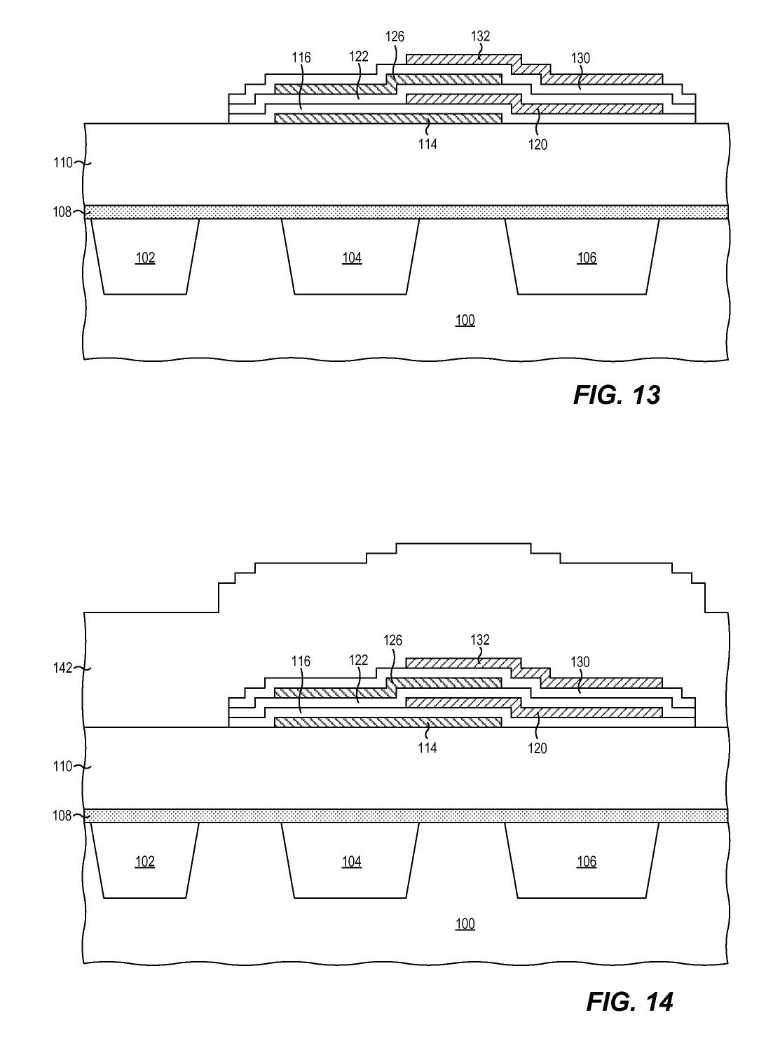

FIGS. 13-16 depict another embodiment of a process flow for manufacturing a stacked MIM capacitor structure. This embodiment may use the same or similar process flow as described above through FIG. 9, but then continues to that shown in FIG. 13. After the stacked MIM capacitor structure is formed, shown here as a four-electrode stack (i.e., three-level capacitor stack), an extra mask may be employed to remove all the capacitor dielectric layers (e.g., capacitor dielectric layers 116, 122, 130) around the desired MIM capacitor structure, using a single subtractive etching step. In other words, the capacitor dielectric layers are removed in areas extending beyond the capacitor electrodes 114, 120, 126, 132.

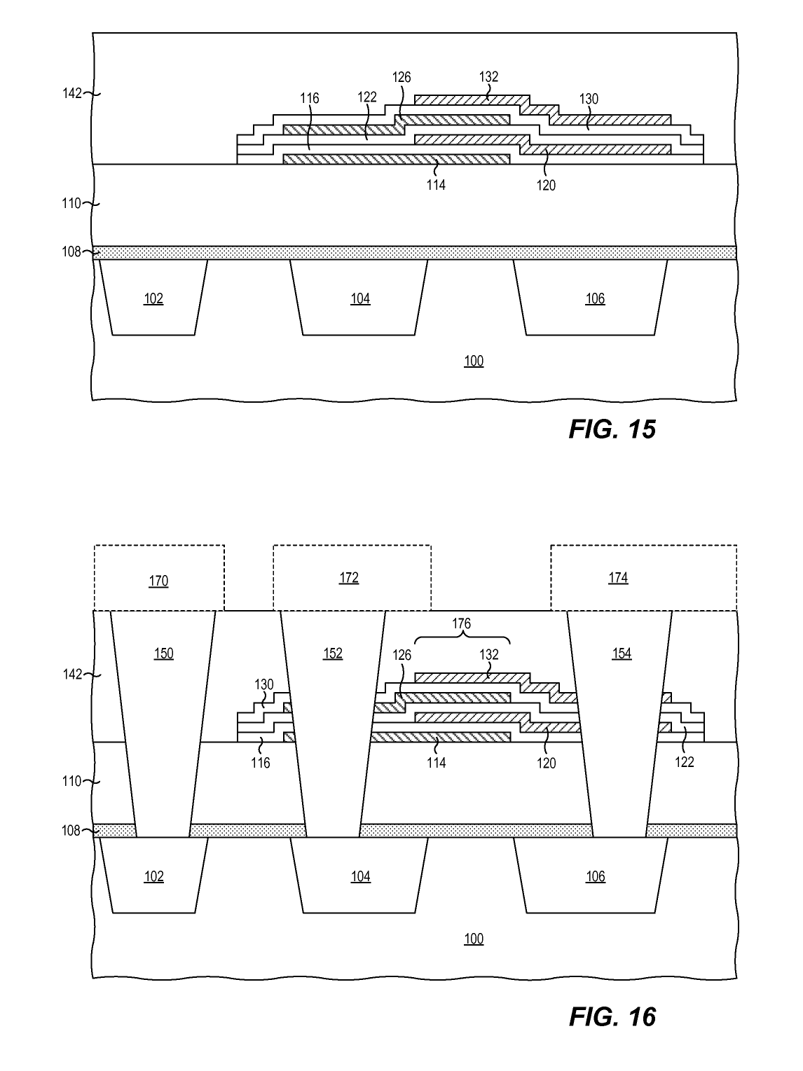

An upper via dielectric layer 142 is deposited to achieve the total desired via dielectric thickness, as before, and which is shown in FIG. 14. The upper surface of this upper via dielectric layer 142 may then be planarized, and the resulting structure is shown in FIG. 15.

Referring now to FIG. 16, vias 150, 152, 154, as before, are formed to contact underlying metal lines 102, 104, 106, respectively. Vias 152, 154 are formed as before, and in the same manner connect to the electrodes of the MIM capacitor structure. However, in this embodiment the via 150 is formed only through upper and lower via dielectric layers 140, 110 because the capacitor dielectric layers 130, 122, 116 do not intersect the sidewall of via 150, and moreover are spaced apart from via 150. By removing the capacitor dielectric layers 130, 122, 116 in regions outside (i.e., around) the MIM capacitor, the parasitic interconnect capacitance of unrelated nodes, such as via 150, as well as unrelated metal lines, such as metal line 102 on the underlying (e.g., Metal-1) layer, and metal line 170 on the overlying (e.g., Metal-2) layer, is reduced. Further, the parasitic capacitance of other Metal-1 lines and Metal-2 lines is reduced, since the capacitor dielectric layers (which may utilize a high-permittivity dielectric) are no longer present outside the MIM capacitor. Because of the effect of fringing fields, the parasitic capacitance between metal lines on the same metal layer may also be reduced.

A stacked planar MIM capacitor structure as described above provides a significant increase in capacitance density relative to a capacitor structure having only one capacitor dielectric layer, yet may be formed using only a single incremental masking step for each additional dielectric layer of the MIM stack, and without requiring a new mask itself (since the first and second masks may be re-used for subsequent levels of the capacitor stack). In the embodiment shown in FIGS. 13-16, one additional mask is also employed, irrespective of the number of levels of the capacitor stack. The number of dielectric/electrode layers that can be added depends on the amount of additional topography that can be tolerated in the process integration, as each additional dielectric/electrode layer creates further topography.

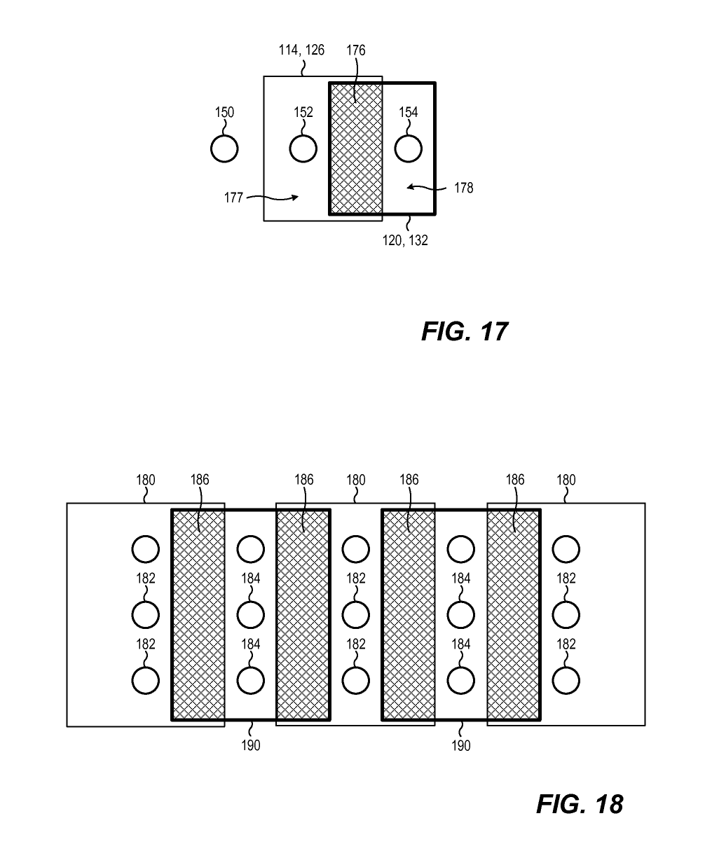

Referring now to FIG. 17, a layout is shown of an embodiment of a stacked MIM capacitor structure that generally corresponds to the embodiments described above. The metal lines 102, 104 106 are not shown, but via 150 connects to metal line 102, via 152 connects to metal line 104, and via 154 connects to metal line 106. Electrodes 114, 126 are patterned with the same mask and thus are shown having coincident edges, with electrode 114 being disposed below electrode 126. Likewise, electrodes 120, 132 are patterned with the same mask and thus are shown having coincident edges, with electrode 120 being disposed below electrode 132. Electrodes 114, 126 are horizontally-staggered relative to electrodes 120, 132.

The MIM capacitor is formed in the overlapping region 176 where electrodes 114, 126 overlap electrodes 120,132. Electrodes 114, 126 extend beyond the overlap region 176 into region 177, but not into region 178, and the via 152 is formed in region 177. Similarly, electrodes 120,132 extend beyond the overlap region 176 into region 178, but not into region 177, and the via 154 is formed in region 178. While one such via 152 is shown, and one such via 154 is shown, in some embodiments two or more vias 152 may be formed in region 177, and two or more vias 154 may be formed in region 178.

The frequency bandwidth performance of such a capacitor is improved by limiting the distance from any point within the capacitor region 176 to the nearest via. As such, a wide, short-depth capacitor region, such as capacitor region 176, provides a good trade-off between high capacitance density and reasonably low-inductance, low-resistance electrodes.

Referring now to FIG. 18, a layout is shown of another embodiment of a stacked MIM capacitor structure. This structure includes several electrodes 180, each of which may represent a single electrode formed on a single electrode layer, or more than one generally-coincident electrodes formed on vertically-alternating electrode layers. Vias 182 are formed through electrodes 180 and make electrical connection to the electrodes 180 by way of the via 182 sidewalls. The electrical connection for each respective via 182 is made circumferentially through the respective via sidewall to each of the set of electrodes 180 through which the respective via 182 is formed.

Similarly, this structure includes several electrodes 190, each of which may represent a single electrode formed on a single electrode layer, or more than one generally-coincident electrodes formed on vertically-alternating electrode layers. Vias 184 are formed through electrodes 190 and make electrical connection to the electrodes 190 by way of the via 184 sidewalls. The electrical connection for each respective via 184 is made circumferentially through the respective via sidewall to each of the set of (e.g., two or more) electrodes 190 through which the respective via 184 is formed. The MIM capacitor is formed collectively in the several overlapping regions 186 where electrodes 180 overlap electrodes 190.

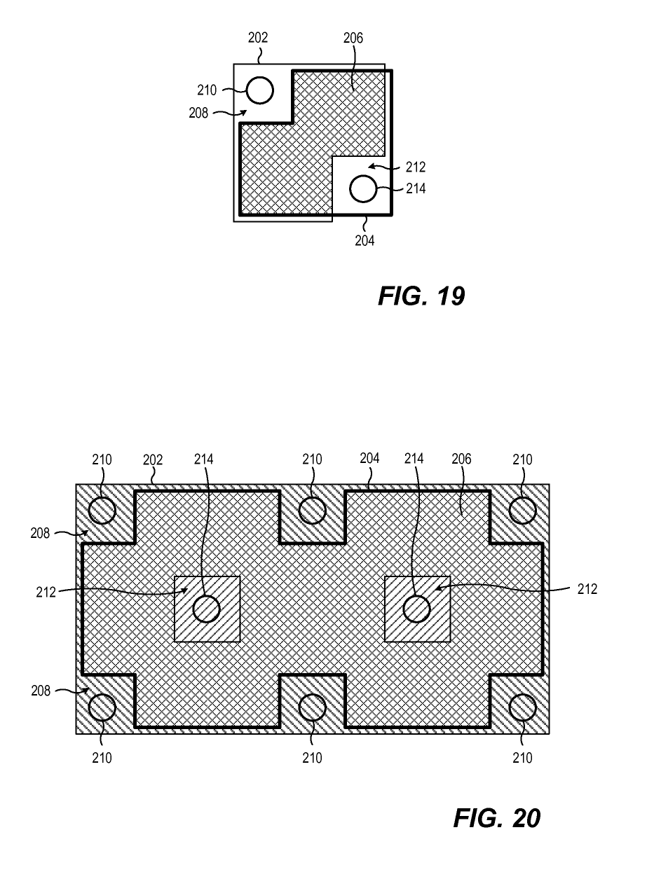

Referring now to FIG. 19, a layout is shown of another embodiment of a stacked MIM capacitor structure. This structure includes a vertical stack of planar electrodes and interposing dielectric layers in an overlap region 206. Electrode 202 represents a first set of one or more electrodes of the vertical stack. Each of the first set of one or more electrodes 202 extends beyond the overlap region 206 to a first region 208 but not to a second region 212. Electrode 204 represents a second set of two or more electrodes of the vertical stack. Each of the second set of two or more electrodes extends beyond the overlap region 206 to the second region 212 but not to the first region 208. The MIM capacitor is formed in the overlapping region 206 where electrodes 202 overlap electrodes 204.

Vias 210, 214 are formed to connect a first conductor layer above the vertical stack to a second conductor layer below the vertical stack. Via 210 is formed in the first region 208 through and is electrically connected at its sidewall to each of the first set of one or more electrodes 202. Via 210 is formed in the second region 212 through and is electrically connected at its sidewall to each of the second set of two or more electrodes 204.

Referring now to FIG. 20, a layout is shown of another embodiment of a stacked MIM capacitor structure. This structure includes a vertical stack of planar electrodes and interposing dielectric layers in an overlap region 206. Electrode 202 (which is shown cross-hatched from upper-left to lower-right) represents a first set of one or more electrodes of the vertical stack. Each of the first set of one or more electrodes 202 extends beyond the overlap region 206 to first regions 208 but not to second regions 212. Electrode 204 (which is shown cross-hatched from upper-right to lower-left) represents a second set of two or more electrodes of the vertical stack. Each of the second set of two or more electrodes extends beyond the overlap region 206 to the second regions 212 but not to the first regions 208. The MIM capacitor is formed in the overlap region 206 where electrodes 202 overlap electrodes 204.

Vias 210, 214 are formed to connect a first conductor layer above the vertical stack to a second conductor layer below the vertical stack. Each of a first set of one or more vias 210 is formed in the first region 208, and is electrically connected at its sidewall to each of the first set of one or more electrodes 202. Each of a second set of one or more vias 214 is formed in the second region 212, and is electrically connected at its sidewall to each of the second set of two or more electrodes 204.

The frequency bandwidth performance of such a MIM capacitor structure is improved by limiting the distance from any point within the capacitor region 206 to the nearest via. As such, the overlap region 206 provides excellent capacitance density, yet maintains reasonably low-inductance, low-resistance electrodes.

In some embodiments, since the MIM capacitor is embedded within the via dielectric between Metal-1 or Metal-2, no significant additional Metal-1 layer or Metal-2 layer resources are expended in order to implement and make contact to such an MIM capacitor.

In some embodiments, halfnium-based (Hf-based) high-permittivity (Hi-K) dielectrics may be used for one or more of the capacitor dielectric layers, and titanium nitride (TiN) may be used for the one or more of the electrode layers. In some embodiments, the via dielectric layers may be a silicon nitride dielectric layer. Deposition, patterning, and etching of such compositions are known in the art. While the embodiments described herein show each via fully enclosed by the electrodes through which it is formed, such is not necessarily required.

While described above in the context of integrated circuit embodiments, other embodiments are also contemplated. For example, such a capacitor structure may be implemented in a silicon interposer that is useful in a three-dimensional packaging application, or other interposer useful to provide electrical connection between two or more integrated circuit dies, and to provide de-coupling capacitance for such dies.

Such a capacitor structure may be used with any kind of integrated circuit technology, such as CMOS, silicon bipolar, SiC, GaAs, GaN, etc., and with virtually any kind of integrated circuit product, but is especially helpful in low-voltage circuits, and high-density circuits, or any circuit for which a high quality, high capacitance density, MIM (i.e., non-voltage-variable) capacitor is useful.

As used herein, each level of a capacitor stack includes a capacitor dielectric layer and a respective electrode above and below the capacitor dielectric layer. An electrode may be shared by a respective capacitor dielectric layer above and below the electrode, so that a two-level capacitor stack may be formed using three electrode layers and two capacitor dielectric layers. For example, the embodiment shown in FIG. 12 shows a three-level capacitor stack formed by four electrodes 114, 120, 126, 132 and three capacitor dielectric layers 116, 122, 130.

As used herein, a “set” includes at least one element or item, and does not necessary require a plurality. As used herein, the word “exemplary” is intended to serve as one example embodiment and not to limit the application by construing the embodiment as preferred or advantageous over other embodiments. The inventive aspects described herein are specifically contemplated to be used alone as well as in various combinations. The invention in several aspects is contemplated to include circuits (including integrated circuits), related methods of fabrication, systems incorporating same, and computer-readable storage media encodings of such circuits and methods and systems, all as described herein in greater detail and as set forth in the appended claims.

While circuits and physical structures have been generally presumed in describing some embodiments of the invention, it is well recognized that in modern semiconductor design and fabrication, physical structures and circuits may be embodied in a computer readable medium as data structures for use in subsequent design, simulation, test, or fabrication stages. For example, such data structures may encode a functional description of circuits or systems of circuits. The functionally descriptive data structures may be, e.g., encoded in a register transfer language (RTL), a hardware description language (HDL), in Verilog, or some other language used for design, simulation, and/or test. Data structures corresponding to embodiments described herein may also be encoded in, e.g., Graphic Database System II (GDSII) data, and functionally describe integrated circuit layout and/or information for photomask generation used to manufacture the integrated circuits. Other data structures, containing functionally descriptive aspects of embodiments described herein, may be used for one or more steps of the manufacturing process.

Computer-readable storage media include non-transitory, tangible computer readable media, e.g., a disk, tape, or other magnetic, optical, semiconductor, or electronic storage medium. In addition to computer-readable storage medium having encodings thereon of circuits, systems, and methods, the computer readable storage media may store instructions as well as data that can be used to implement embodiments described herein or portions thereof. The data structures may be utilized by software executing on one or more processors, firmware executing on hardware, or by a combination of software, firmware, and hardware, as part of the design, simulation, test, or fabrication stages.

References in the claims to a numbered item, such as a “third” item, are for clarity, and do not necessarily imply that lower-numbered items of the same type are also included in the recited claim.

The foregoing detailed description has described only a few of the many possible implementations. For this reason, this detailed description is intended by way of illustration, and not by way of limitations. Variations and modifications of the embodiments disclosed herein may be made based on the description set forth herein. It is only the following claims, including all equivalents, that are intended to define the invention.

What is claimed is:

1. A method for fabricating a metal-insulator-metal (MIM) capacitor structure, said method comprising:
forming a vertical stack of planar electrodes and interposing dielectric layers in an overlap region, each of a first set of one or more electrodes of the vertical stack extending beyond the overlap region to a first region but not to a second region, and each of a second set of two or more electrodes of the vertical stack extending beyond the overlap region to the second region but not to the first region;
forming vias for a first conductor layer above the vertical stack to a second conductor layer below the vertical stack, each via having a sidewall, each of a first set of one or more of said vias formed in the first region through and electrically connected at its sidewall to each of the first set of one or more electrodes of the vertical stack, and each of a second set of one or more of said vias formed in the second region through and electrically connected at its sidewall to each of the second set of two or more electrodes of the vertical stack.

2. The method as recited in claim 1 further comprising:
after said forming a vertical stack of planar electrodes and interposing dielectric layers, and before said forming vias, removing the interposing dielectric layers outside the planar electrodes.

3. The method as recited in claim 1 further comprising:
before said forming a vertical stack of planar electrodes and interposing dielectric layers, forming a lower via dielectric layer; and
after said forming a vertical stack of planar electrodes and interposing dielectric layers, and before said forming vias, forming an upper via dielectric layer;
wherein each of said vias is formed through the upper via dielectric layer and through the lower via dielectric layer to connect the first conductor layer to the second conductor layer.

4. The method as recited in claim 1 wherein:
each electrode of the first set of one or more electrodes is vertically adjacent to an electrode of the second set of two or more electrodes; and
vertically-adjacent electrodes are horizontally-staggered.

5. The method as recited in claim 1 wherein:
each electrode of the first set of one or more electrodes is patterned using a first mask; and
each electrode of the second set of two or more electrodes is patterned using a second mask.

6. The method as recited in claim 1 wherein:
each respective via is fully enclosed by each of the respective set of electrodes through which the respective via is formed; and
the electrical connection for each respective via is made circumferentially through the respective via sidewall to each of the respective set of electrodes through which the respective via is formed.

7. The method as recited in claim 1 wherein:
the first set of one or more of said vias comprises multiple vias; and
the second set of one or more of said vias comprises multiple vias.

8. The method as recited in claim 1 wherein each of the interposing dielectric layers comprises a halfnium-based dielectric.

9. The method as recited in claim 1 wherein said forming a vertical stack of planar electrodes and interposing dielectric layers comprises:
patterning a first electrode layer using a first mask to form a first electrode; then
patterning a second electrode layer using a second mask different than the first mask to form a second electrode that is horizontally-staggered relative to the first electrode; and then
patterning a third electrode layer using the first mask to form a third electrode that is horizontally-aligned with the first electrode.

10. The method as recited in claim 9 further comprising:
after said forming a vertical stack of planar electrodes and interposing dielectric layers, and before said forming vias, removing the interposing dielectric layers outside the first, second, and third electrodes.

11. An apparatus including a metal-insulator-metal (MIM) capacitor structure comprising:
a vertical stack of planar electrodes and interposing dielectric layers in an overlap region, each of a first set of one or more electrodes of the vertical stack extending beyond the overlap region to a first region but not to a second region, and each of a second set of two or more electrodes of the vertical stack extending beyond the overlap region to the second region but not to the first region; and
plural vias from a first conductor layer above the vertical stack to a second conductor layer below the vertical stack, each via having a sidewall, each of a first set of one or more of said vias formed in the first region through and electrically connected at its sidewall to each of the first set of one or more electrodes of the vertical stack, and each of a second set of one or more of said vias formed in the second region through and electrically connected at its sidewall to each of the second set of two or more electrodes of the vertical stack.

12. The apparatus as recited in claim 11 wherein:
the interposing dielectric layers are disposed within the vertical stack of planar electrodes, and are absent outside the vertical stack of planar electrodes.

13. The apparatus as recited in claim 11 further comprising:
a lower via dielectric layer between the second metal layer and the vertical stack; and
an upper via dielectric layer between the first metal layer and the vertical stack;
wherein each of said vias is formed through the upper via dielectric layer and through the lower via dielectric layer to connect the first conductor layer to the second conductor layer.

14. The apparatus as recited in claim 11 wherein:
each electrode of the first set of one or more electrodes is vertically adjacent to an electrode of the second set of two or more electrodes; and
vertically-adjacent electrodes are horizontally-staggered.

15. The apparatus as recited in claim 11 wherein:
each respective via is fully enclosed by each of the respective set of electrodes through which the respective via is formed; and
the electrical connection for each respective via is made circumferentially through the respective via sidewall to each of the respective set of electrodes through which the respective via is formed.

16. The apparatus as recited in claim 11 wherein:
the first set of one or more of said vias comprises multiple vias; and
the second set of one or more of said vias comprises multiple vias.

17. The apparatus as recited in claim 11 wherein:
the second set of two or more electrodes comprises a first electrode and a third electrode that is above and horizontally-aligned with the first electrode;
the first set of one or more electrodes comprises a second electrode that is above and horizontally-staggered relative to the first electrode, and below the third electrode; and
the interposing dielectric layers comprise a first interposing dielectric layer between the first and second electrodes, and a second interposing dielectric layer between the second and third electrodes.

18. The apparatus as recited in claim 11 wherein the metal-insulator-metal capacitor structure is disposed on an integrated circuit.

19. The apparatus as recited in claim 11 wherein the metal-insulator-metal capacitor structure is disposed on an interposer structure.

20. A computer readable storage medium comprising data structures encoding an aspect of a metal-insulator-metal (MIM) capacitor structure, said MIM capacitor structure comprising:
a vertical stack of planar electrodes and interposing dielectric layers in an overlap region, each of a first set of one or more electrodes of the vertical stack extending beyond the overlap region to a first region but not to a second region, and each of a second set of two or more electrodes of the vertical stack extending beyond the overlap region to the second region but not to the first region; and
plural vias from a first conductor layer above the vertical stack to a second conductor layer below the vertical stack, each via having a sidewall, each of a first set of one or more of said vias formed in the first region through and electrically connected at its sidewall to each of the first set of one or more electrodes of the vertical stack, and each of a second set of one or more of said vias formed in the second region through and electrically connected at its sidewall to each of the second set of two or more electrodes of the vertical stack.

21. The computer readable storage medium as recited in claim 20 wherein:
the interposing dielectric layers are disposed within the vertical stack of planar electrodes, and are absent outside the vertical stack of planar electrodes.

22. The computer readable storage medium as recited in claim 20 wherein said MIM capacitor structure further comprises:
a lower via dielectric layer between the second metal layer and the vertical stack; and
an upper via dielectric layer between the first metal layer and the vertical stack;
wherein each of said vias is formed through the upper via dielectric layer and through the lower via dielectric layer to connect the first conductor layer to the second conductor layer.

23. The computer readable storage medium as recited in claim 20 wherein:
each respective via is fully enclosed by each of the respective set of electrodes through which the respective via is formed; and
the electrical connection for each respective via is made circumferentially through the respective via sidewall to each of the respective set of electrodes through which the respective via is formed.
